(19) United States
(12) Patent Application Publication
(10) Pub. No.: US 2011/0163298 A1
(43) Pub. Date: Jul. 7, 2011

(54) Graphene and Hexagonal Boron Nitride Devices

(76) Inventor: Chien-Min Sung, Tansui (TW)

(21) Appl. No.: 12/955,505

(22) Filed: Nov. 29, 2010

Related U.S. Application Data
(60) Provisional application No. 61/292,098, filed on Jan. 4, 2010.

(51) Int. Cl. H01L 29/15; G03H 1/02; G01H 5/00

(52) U.S. Cl. 257/29; 359/3; 73/645; 73/861.27; 257/E29.072

(57) ABSTRACT

Graphene layers, hexagonal boron nitride (hBN) layers, as well as other materials made of primarily sp2 bonded atoms and associated methods are disclosed. In one aspect, the present invention provides graphene and hBN devices. In one aspect, for example, an electronic device is provided including a graphene layer and a planar hBN layer operably associated with the graphene layer and forming a functional interface therebetween. Numerous functional interfaces are contemplated, depending on the desired functionality of the device.

### PRIORITY DATA

This application claims the benefit of U.S. Provisional Patent Application Ser. No. 61/292,098 filed Jan. 4, 2010, which is incorporated herein by reference.

### FIELD OF THE INVENTION

The present invention relates generally to graphene and hexagonal boron nitride devices and associated methods. Accordingly, the present invention involves the chemical and material science fields.

### BACKGROUND OF THE INVENTION

Graphene is often defined as a one-atom-thick planar sheet of sp2-bonded carbon atoms that are densely packed into a benzene-ring structure in a honeycomb crystal lattice. This two-dimensional material exhibits high electron mobility in the plane of the layer, as well as exceptional thermal conductivity. Graphite is comprised of multiple layers of graphene stacked parallel to one another.

Graphene is widely used to describe properties of many carbon-based materials, including graphite, large fullerenes, nanotubes, etc. For example, carbon nanotubes may be described as graphene sheets rolled up into nanometer-sized cylinders. Furthermore, planar graphene itself has been presumed not to exist in the free state, being unstable with respect to the formation of curved structures such as soot, fullerenes, and nanotubes.

Attempts have been made to incorporate graphene into electronic devices such as transistors, however such attempts have generally been unsuccessful due to problems associated with the production of high quality graphene layers of a size suitable for incorporation into such devices. One technique for generating graphene layers involves peeling graphene planes from highly oriented pyrrolitic graphite. Using such methods, only small flakes are produced that are generally too small to be utilized in electronic applications.

### SUMMARY OF THE INVENTION

The present invention provides graphene and hexagonal boron nitride (hBN) devices. In one aspect, for example, an electronic device is provided including a graphene layer and a planar hBN layer operably associated with the graphene layer and forming a functional interface therebetween. Numerous functional interfaces are contemplated, depending on the desired functionality of the device.

In one aspect, the functional interface is an insulative functional interface. Various configurations are contemplated whereby an insulative functional interface can be useful, and nearly any use or device incorporating such an interface should be considered to be within the present scope. For example, in one specific aspect, the graphene layer is an electronic circuit, and the hBN layer is positioned to electrically insulate the graphene layer and is operable to conduct heat from the electronic device. In another aspect, the graphene layer is a plurality of graphene circuit layers at least partially isolated from one another by the hBN layer.

In another aspect the functional interface is a semiconductive functional interface. Various configurations are contemplated whereby a semiconductive functional interface can be useful, and any use or device incorporating such an interface should be considered to be within the present scope. In one specific aspect, for example, the device can include a power source, where the graphene layer has a plurality of conductive traces electrically coupled to the power supply and intersecting at a plurality of address points, and where the hBN layer as a plurality of light-emitting semiconductors located between the plurality of conductive traces at the plurality of address points. Power from the power supply applied to the address points is operable to cause light to emit from the light-emitting semiconductor. In one specific aspect the individual light-emitting semiconductors are a plurality of doped hBN layers stacked on one another. In another aspect, a phosphor layer is functionally associated with the light-emitting semiconductor, wherein the phosphor layer is operable to emit colored light upon excitation by light from the light-emitting semiconductor. In yet another aspect, the plurality of light-emitting semiconductors are associated together in groups of at least two in order to form a plurality of pixels, wherein the light-emitting semiconductors of individual pixels includes at least two phosphor layers capable of emitting at least two different color lights. Additional phosphor layers can be used as desired. In one specific aspect, such a device can be an electronic display.

In another aspect the functional interface is a capacitative functional interface. Various configurations are contemplated whereby a capacitative functional interface can be useful, and nearly any use or device incorporating such an interface should be considered to be within the present scope. In one specific aspect, for example, the graphene layer and the hBN layer are positioned in an alternating relationship, and wherein the alternating relationship forms the capacitative functional interface. In another aspect, the graphene layer is a plurality of graphene layers and the hBN layer is a plurality of hBN layers, and the plurality of graphene layers and the plurality of hBN layers are alternated to form the alternating relationship. In yet another aspect the graphene layer and the hBN layer are rolled together to form the alternating relationship. Additionally, in one aspect metal atoms are intercalated in the hBN layer.

There has thus been outlined, rather broadly, various features of the invention so that the detailed description thereof that follows may be better understood, and so that the present contribution to the art may be better appreciated. Other features of the present invention will become clearer from the following detailed description of the invention, taken with the accompanying claims, or may be learned by the practice of the invention.

### BRIEF DESCRIPTION OF THE DRAWINGS

FIG. 1 is a graphical representation of an electronic device in accordance with one embodiment of the present invention.

FIG. 2 is a graphical representation of an electronic device in accordance with another embodiment of the present invention.

FIG. 3 is a graphical representation of an electronic device in accordance with yet another embodiment of the present invention.

FIG. 4 is a graphical representation of an electronic device in accordance with a further embodiment of the present invention.

### DETAILED DESCRIPTION OF THE INVENTION

Definitions

In describing and claiming the present invention, the following terminology will be used in accordance with the definitions set forth below.

The singular forms “a,” “an,” and, “the” include plural referents unless the context clearly dictates otherwise. Thus, for example, reference to “a layer” includes reference to one or more of such layers, and reference to “the material” includes reference to one or more of such materials.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “functional interface” refers to an interface between disparate materials that has a defined function. For example, the interface between graphene and hBN is a functional interface that has a defined function based on the properties of the specific graphene and hBN materials used. Additionally, the interface between different types of graphene material, or between different types of hBN can also be considered to be a functional interface. Non-limiting examples of defined functions can include conductive, semiconductive, capacitative, and insulative functions.

As used herein, the term “about” is used to provide flexibility to a numerical range endpoint by providing that a given value may be “a little above” or “a little below” the endpoint.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually. This same principle applies to ranges reciting only one numerical value as a minimum or a maximum. Furthermore, such an interpretation should apply regardless of the breadth of the range or the characteristics being described.

The Invention

The present invention relates to novel graphene and hexagonal boron nitride (hBN) devices. Furthermore, the scope of the present invention should include not only various electronic devices themselves, but also subparts and materials used in the construction of such devices.

Graphene is a one-atom-thick planar sheet of sp2-bonded carbon atoms that are densely packed into a carbon-ring structure in a honeycomb crystal lattice. The carbon-carbon bond length in graphene is approximately 1.45 Å, which is shorter than that of diamond at 1.54 Å. Graphene is the basic structural element of other graphitic materials including graphite, carbon nanotubes, fullerenes, etc. It should be noted that the term “graphene” according to aspects of the present invention includes reference to both single atom layers of graphene and multiple layer stacks of graphene.

Perfect graphene planes consist exclusively of hexagonal cells and have few if any grain boundaries. Any pentagonal or heptagonal cells within a graphene plane would constitute “defects” that alter the planar nature of the graphene layer. For example, a single pentagonal cell warps the plane into a cone shape, while 12 pentagons at the proper locations would create a fullerene of the plane. Also, a single heptagon warps the plane into a saddle-shape. Warpage of the graphene plane tends to reduce electron mobility and thermal conductivity, and thus in some aspects may be undesirable for applications where these properties are valued.

The physical characteristics of graphene layers can make it a beneficial material to incorporate into a variety of devices. Numerous devices and uses are contemplated, and the following examples should not be seen as limiting. For example, in one aspect, the high electron mobility of graphene can make it a useful component of integrated circuits. In another aspect, graphene can be used as a sensor for single or multiple molecule detection, including gasses. The 2D structure of a graphene layer effectively exposes the entire volume of the graphene material to a surrounding environment, thus making it an efficient material for the detection of molecules. Such molecule detection can be measured indirectly because, as a gas molecule adsorbs to the surface of graphene, the location of absorption will experience a detectable local change in electrical resistance. Graphene is a useful material for such detection due to its high electrical conductivity and low noise. In another aspect, a graphene layer can be utilized as a surface acoustic wave (SAW) filter. In this case, a voltage signal can be transmitted due to the resonance of the graphene material. In yet another aspect, graphene may be utilized as a pressure sensor. As the graphene lattice is deflected under pressure, electrical resistance changes can be detected to allow a measurement of such pressure. In a further aspect, graphene layers may be utilized as transparent electrodes for LED, LCD, and solar panel applications. Additionally, graphene can be co-rolled with an insulative material such as a Mylar® film to produce a capacitor. Additionally, graphene can be co-rolled with insulative hBN to produce an excellent capacitor material. Furthermore, graphene can be layered on a semiconductive material such as silicon, and etched to produce electrical interconnects for an electrical device.

In some aspects of the present invention, graphene layers can be doped with a variety of dopants. Dopants can be utilized to alter the physical properties of a graphene layer, and/or they can be utilized to alter the physical interactions between graphene layers within a stack of graphene layers. Such doping can occur during formation of the graphene layer, or it can occur following the formation of the graphene layer by depositing the dopant in the layer. By doping with boron, for example, a P-type semiconductor can be formed. A variety of dopants can be utilized for doping the graphene layers. Specific non-limiting examples can include boron, phosphorous, nitrogen, and combinations thereof. Doping can also be utilized to alter the electron mobility of specific regions of the graphene layer for the formation of circuits within the layer. Such site specific doping can allow the patterning of electrical circuits within a layer of graphene. Furthermore, while graphene layers have a high electron mobility, conductivity between graphene layers in a stack is more limited. By doping with metal atoms or other conductive materials, the electron mobility between stacked layers can be increased.

hBN is a one-atom-thick planar sheet that, in this case, is made of sp2-bonded boron nitride atoms that are densely packed into a planar crystal lattice. Such layers can include single hBN layers or stacks of multiple hBN layers. Furthermore, the hBN layers according to aspects of the present invention are high quality materials having few if any grain boundaries. The physical characteristics of hBN make it a beneficial material to incorporate into a variety of devices. For example, hBN can have the shortest bond lengths (1.42 A) of solids. As a result, this material possesses a large band gap, and is thus capable of emitting deep ultraviolet radiation. This property can be very useful for nanometer lithography and forming white LEDs via UV excited phosphor techniques. P-N junctions can be created for making transistors that can be formed in-situ with graphene interconnected circuits. In another example, graphene or mono BN also possess high sound speed and thermal conductivity. Because of this, they can be utilized as ultrahigh frequency surface acoustic wave filters, ultrasound generators, and heat spreaders. Due to the hexagonal symmetry, the materials are also piezoelectric. In other examples, graphene or BN layers can be used as sensors for chemisorbed gasses, delicate electrodes for analyzing PPB levels of ions (e.g. Pb) in water solutions by electrolysis, transparent electrodes with hydrogen termination, etc.

In some aspects of the present invention, hBN layers can be doped with a variety of dopants. Dopants can be utilized to alter the physical properties of a hBN layer, and/or they can be utilized to alter the physical interactions between hBN layers within a stack. Such doping can occur during formation of the hBN layer by adding the dopant to the mold assembly, or it can occur following the formation of the hBN layer by depositing the dopant in the layer. A variety of dopants can be utilized for doping the hBN layers. Specific non-limiting examples can include silicon, Mg, and combinations thereof. Doping the hBN with silicon results in an N-type semiconductor material.

The present invention also provides graphene/hBN composite materials. In one aspect, for example, an electrical precursor material can include a composite material comprising a graphene layer and a hBN layer disposed on the graphene layer. In one specific aspect, the composite material comprises a plurality of alternating graphene layers and hBN layers. These layers can be utilized in a variety of electronic components, as would be understood by one of ordinary skill in the art.

A variety of devices are contemplated that incorporate hBN and graphene layers. For example, as hBN layers have a high band gap, they are also good insulators. By alternating graphene and hBN layers, an effective capacitative material is produced. This material can be produced in stacked, planar arrangements, or the layers can be rolled together in a composite cylindrical arrangement. Other potential uses include three dimensional integrated circuits of boron nitride transistors connected by graphene interconnects, batteries, solar cells, notebooks, cell phones, and the like. Three dimensional integrated circuits have previously been problematic to design, due primarily to thermal management difficulties. The high thermal conductivities of graphene and hBN materials, however, facilitate the movement of heat from within the three dimensional circuit, thus at least partially overcoming such thermal management issues. Additionally, parallel-stacked solar cells can be produced due to the thin cross section of these materials. Further uses include gas and microbe sensors, as well as DNA and protein chips.

These composite materials can be made by bringing preformed graphene and hBN layers together, or by forming one layer on another layer. For example, in one aspect a method of making a graphene/hBN composite material can include providing a template having a graphene layer disposed on a substrate, and depositing a boron nitride source material on the graphene layer to form a hBN layer thereon. Thus the graphene layer is utilized during the deposition as a template for the hBN layer. The hBN layer can be deposited by any known method, including CVD and PVD processes. Additionally, a graphene layer can be deposited using a hBN layer as a template.

Accordingly, a variety of electronic devices are contemplated that can incorporate graphene, hexagonal boron nitride, or both. Thus it should be understood that the present invention should not be limited to the examples shown herein, but to any electronic devices incorporating such materials. In one aspect of the present invention, for example, an electronic device is provided including a graphene layer and a planar hBN layer operably associated with the graphene layer and forming a functional interface therebetween. Various functional interfaces can be created using graphene and hBN, a few non-limiting examples of which are discussed below.

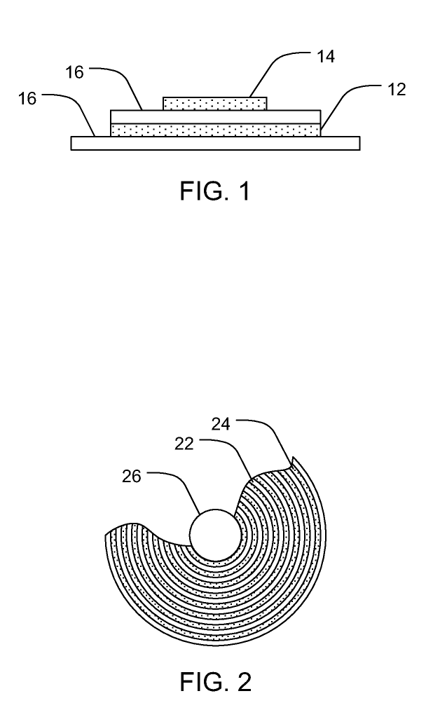

In one aspect of the present invention, the functional interface can be an insulative functional interface. An insulative functional interface is an interface whereby the graphene is insulated by the hBN material. Various configurations of graphene and hBN are contemplated. In one aspect, for example, the graphene can be an electronic circuit, and the hBN is positioned to electrically insulate the graphene. Additionally, the thermal properties of hBN function to conduct heat from the electronic device via this insulative material. In some aspects, the graphene layer is multiple graphene circuit layers that are at least partially isolated from one another by the hBN layer or hBN layers. As is shown in FIG. 1, for example, a first graphene circuit 12 can be electrically insulated from a second graphene circuit 14 by one or more hBN layers 16. Thus the hBN layers 16 function to isolate the graphene circuit elements 12, 14 from one another while at the same time conducting heat from the electronic device.

In another aspect of the present invention, the functional interface is a capacitative functional interface. A capacitative functional interface is an interface whereby the graphene and the hBN materials interact as dielectric materials. Various configurations of the graphene layer and the hBN layers are contemplated to provide this functionality. For example, in one aspect the graphene layer and the hBN layer are positioned in an alternating relationship. Such an alternating relationship includes one or more layer of each material in an alternating configuration. The conductive properties of the graphene and the insulative properties of the hBN form an effective capacitative interface when positioned in such an alternating relationship. In one specific aspect, the graphene layer is a plurality of graphene layers and the hBN layer is a plurality of hBN layers that are alternated to form a stacked relationship. In another aspect, the graphene layer and the hBN layer are rolled together to form the alternating relationship. As is shown in FIG. 2, a graphene layer 22 and a hBN layer 24 can be rolled together to form a cylindrical capacitor. The layers can be rolled around a center material 26 that can be conductive, non-conductive, or semiconductive. Additionally, the portion of the capacitor indicated at 26 can be a space, or it can be a portion of the graphene and/or hBN layers. Additionally, in one aspect metal atoms can be intercalated in the hBN layer in order to alter the conductivity of the hBN layer. Such a device can also be used to store electrons as a battery.

A similar capacitative device can also be made of alternating graphene layers. For example, graphene layers that have insulative properties between adjacent layers can be alternated or rolled together to form a capacitor. Such an insulative graphene material can be made by hydrogenating (graphane) or halogenating graphene material. One example of a halogen that may be used is fluorine.

In another aspect of the present invention, the functional interface is a semiconductive functional interface. A semiconductive functional interface is an interface whereby the graphene and/or the hBN materials interact as semiconductor materials. Various configurations of the graphene layer and the hBN layers are contemplated to provide this functionality. The graphene layer, the hBN layer, or both the graphene layer and the hBN layer can be doped as has been described herein.

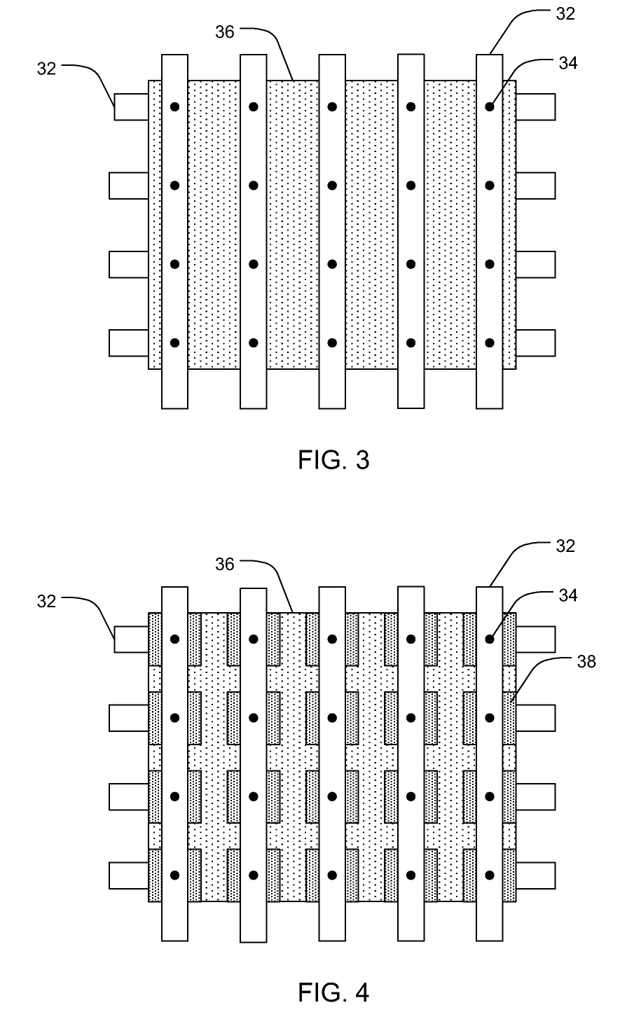

A wide variety of semiconductive devices are contemplated, including the various examples described herein, such as transistors, solar cells, LEDs, LCDs, ICs, and the like. In one specific aspect, a display device is provided. As is shown in FIG. 3, the display device includes a plurality of graphene strips 32 that function as a plurality of conductive traces that intersect at a plurality of address points 34. The graphene strips 32 are shown in FIG. 3 in a perpendicular relationship, and it should be noted that any angular relationship between the strips that allows the functionality of the device should be considered to be within the present scope. The graphene strips are electrically coupled to a power supply (not shown) and a switching system (not shown). Thus flowing current through at least two intersecting graphene strips allows current to flow through the address point associated with the intersection between these intersecting graphene strips. The device further includes a hBN layer 36 disposed between the intersecting graphene strips 32. The hBN layer 36 is a light-emitting semiconductor that is formed by doping and stacking hBN layers. In some aspects the hBN layer can be doped at the address points, or in other aspects all or substantially all of the hBN layer can be doped. Thus when an address point is activated, the associated current causes the light-emitting semiconductor at that position to emit light.

In another aspect, as is shown in FIG. 4, a phosphor layer 38 is functionally associated with the light-emitting semiconductor 36. The phosphor layer emits colored light upon excitation by light from the light-emitting semiconductor, thus allowing a variety of colors to be displayed. The address points and the phosphor layers can also be arranged so as to create pixels that are capable of displaying a variety of colors. A pixel can be formed from at least two light-emitting semiconductor regions associated with at least two address points and at least two different phosphor layers capable of emitting at least two different colored lights. In some aspects, a pixel can include at least three light-emitting semiconductor regions associated with at least three address points and at least three different phosphor layers capable of emitting at least three different colored lights.

The present invention also provides sensor chips. In one aspect, for example, a sensor chip includes a graphene surface functionalized with a plurality of antigens. For example, amine groups can be used to couple antigens to a graphene matrix. A biological fluid containing antibodies can be delivered over the graphene matrix to allow binding between matching antibodies and antigens. Once the biological fluid has been washed away, positive identifications of such matches can be made.

The present invention also provides data and/or holographic storage devices. Such a device includes a graphene surface terminated in a pattern with a plurality of hydrogen atoms and a plurality of halogen atoms. The pattern thus codes for a storage or holographic pattern representing data. The data can be retrieved using a laser as raw data or as a holographic image.

The present invention also provides molecular assay devices. In one aspect, for example, such a device can include a planar hBN surface and a power source coupled to the hBN surface. The hBN surface has an asymmetrical lattice that can be induced with an electromagnetic pulse. Unidentified molecules can be attached to a portion of the hBN lattice. The attenuation of sound speed across the hBN due to unidentified molecules can provide molecular information such as molecular weight that can be a quantitative measure of the unknown molecule. The device can be used to determine the weight of molecules, compounds, bacteria, viruses, and the like, by measuring the time delay from one end of the hBN layer to the other. Due to the large area of involved with the hBN surface, very accurate measurements can be taken with high resolution.

The present invention also provides devices capable of chemical storage. For example, in one aspect the interface between graphene and hBN can be used to store hydrogen, either as molecules (H₂) or as atoms. In the latter case, intercalated Pd or Ni could be used as a catalyst to split H₂ molecules into H atoms. The stored hydrogen can be released by heating or by applying voltage. In one aspect, such a device can be used for hydrogen storage in conjunction with devices utilizing hydrogen as a fuel source. In another aspect, such hydrogen storage can be used as the anode of lithium battery.

The present invention also provides devices capable of electron storage. For example, in one aspect electrons can be attracted to graphene layers that are separated by insulating hBN layers. In this way a compact battery is formed for storing electricity.

The present invention also provides materials capable of being used in night vision devices. For example, in one aspect the hBN layer of an hBN/graphene composite can be doped (e.g. with C to form BC₂N) to absorb IR. The underlying graphene layer can be patterned to form orthogonal matrices, on opposite sides or on the same side, in order to pick up photoelectricity.

The present invention also provides devices capable of being used in biomolecular assay chips or arrays. In one aspect, for example, a DNA chip or array can be created by functionalizing hBN or graphene or an hBN/graphene composite with amine, oxyl, or carboxy termination. Nucleic acids and amino acids can be absorbed on the surface at a high concentration, and heating will release such amino acids for biological applications. Also, peptides can be spread over the hBN surface to assay DNA molecules.

The present invention also provides devices capable of being used for terra Hertz communication devices. Due to the high stiffness of graphene or hBN surfaces, high frequency vibrations can be amplified with a boundary frame. This can be used as a generator for ultrasound “laser” devices by accumulating sufficient resonance energy.

Various additional details of hBN and graphene materials including methods for the production and use thereof can be found in Applicant's copending U.S. Patent Application Nos. 61/079,064, 61/145,707, 61/259,948, Ser. No. 12/499,647, Ser. No. 12/713,004, and Ser. No. 12/899,786, each of which are incorporated herein by reference.

Various processing techniques can be applied to graphene. In one aspect, for example, the surface of a graphene layer can be functionalized to create various materials having different electrical, mechanical, and/or chemical properties. In one aspect, one or more graphene surfaces can be hydrogenated to form graphane. A number of other functional groups may be covalently or ionically attached to graphene and/or hBN with sufficient surface preparation, such as carboxyl groups, halides, such as fluoride, chloride, bromide, metals, endocytic groups, and other carbon containing chains. Such functional groups may serve as intermediate ligand-type attachments for additional molecules, or may be a terminal attachment in and of themselves when they have a specifically desired function.

Additionally, wrinkles or folds in the graphene film can be straightened or mended by heating due to the thermal contraction of sp2 bonds. Hydrogenating the graphene material into graphane can also straighten the layer. In some cases, the material can be heated in a hydrogen atmosphere to mend and straighten the graphene.

Of course, it is to be understood that the above-described arrangements are only illustrative of the application of the principles of the present invention. Numerous modifications and alternative arrangements may be devised by those skilled in the art without departing from the spirit and scope of the present invention and the appended claims are intended to cover such modifications and arrangements. Thus, while the present invention has been described above with particularity and detail in connection with what is presently deemed to be the most practical and preferred embodiments of the invention, it will be apparent to those of ordinary skill in the art that numerous modifications, including, but not limited to, variations in size, materials, shape, form, function and manner of operation, assembly and use may be made without departing from the principles and concepts set forth herein.

What is claimed is:

1. An electronic device, comprising:
a graphene layer; and
a planar hBN layer operably associated with the graphene layer and forming a functional interface therebetween.

2. The device of claim 1, wherein the functional interface is an insulative functional interface.

3. The device of claim 2, wherein the graphene layer is an electronic circuit, and the hBN layer is positioned to electrically insulate the graphene layer and operable to conduct heat from the electronic device.

4. The device of claim 2, wherein the graphene layer is a plurality of graphene circuit layers at least partially isolated from one another by the hBN layer.

5. The device of claim 1, wherein the functional interface is a semiconductive functional interface.

6. The device of claim 5, further comprising:
a power source;
the graphene layer as a plurality of conductive traces electrically coupled to the power supply and intersecting at a plurality of address points;
the hBN layer as a plurality of light-emitting semiconductors located between the plurality of conductive traces at the plurality of address points, wherein power from the power supply applied to the address points is operable to cause light to emit from the light-emitting semiconductor.

7. The device of claim 6, wherein individual light-emitting semiconductors are a plurality of doped hBN layers stacked on one another.

8. The device of claim 6, further comprising a phosphor layer functionally associated with the light-emitting semiconductor, the phosphor layer being operable to emit colored light upon excitation by light from the light-emitting semiconductor.

9. The device of claim 8, wherein the plurality of light-emitting semiconductors are associated together in groups of at least two to form a plurality of pixels, and wherein the light-emitting semiconductors of individual pixels includes at least two phosphor layers capable of emitting at least two different color lights.

10. The device of claim 8, wherein the device is an electronic display.

11. The device of claim 1, wherein the functional interface is a capacitative functional interface.

12. The device of claim 11, wherein the graphene layer and the hBN layer are positioned in an alternating relationship, and wherein the alternating relationship forms the capacitative functional interface.

13. The device of claim 12, wherein the graphene layer is a plurality of graphene layers and the hBN layer is a plurality of hBN layers, and wherein the plurality of graphene layers and the plurality of hBN layers are alternated to form the alternating relationship.

14. The device of claim 12, wherein the graphene layer and the hBN layer are rolled together to form the alternating relationship.

15. The device of claim 14, further comprising metal atoms intercalated in the hBN layer.

16. A sensor chip, comprising a graphene surface functionalized with a plurality of antigens.

17. A holographic storage device, comprising a graphene surface terminated in a pattern with a plurality of hydrogen atoms and a plurality of halogen atoms, wherein holographic data is represented in the pattern of hydrogen atoms and halogen atoms.

18. An integrated circuit interconnect, comprising a plurality of graphene circuits interconnecting at least two electronic components.

19. A SAW filter, comprising a planar hBN surface and a power source coupled to the hBN surface, the hBN surface being operable to couple to a test substance and measure molecular weight based on attenuation of sound speed across the test substance.
